(19) United States
(12) Patent Application Publication
(10) Pub. No.: US 2025/0126626 A1
(43) Pub. Date: Apr. 17, 2025

(54) WIRELESS COMMUNICATION DEVICE USING PLURALITY OF DEINTERLEAVING BUFFERS AND OPERATING METHOD THEREOF

(71) Applicant: Samsung Electronics Co., Ltd., Suwon-si (KR)

(72) Inventor: Juhyuk IM, Suwon-si (KR)

(73) Assignee: Samsung Electronics Co., Ltd., Suwon-si (KR)

(21) Appl. No.: 18/904,335

(22) Filed: Oct. 2, 2024

(30) Foreign Application Priority Data
Oct. 17, 2023 (KR) 10-2023-0138927

(51) Int. Cl. H04W 72/25; H03M 13/39; H04W 4/40

(52) U.S. Cl. CPC H04W 72/25; H03M 13/3927; H04W 4/40

(57) ABSTRACT

An operation method of a wireless communication device for performing sidelink-based vehicle-to-everything (V2X) communication includes decoding first sidelink control information (SCI) to obtain a first decoding result, the first SCI being contained in a received physical sidelink control channel (PSCCH), decoding second SCI including obtaining a plurality of log likelihood ratio (LLR) values by demodulating the second SCI, storing the plurality of LLR values in a plurality of deinterleaving buffers such that the plurality of LLR values are deinterleaved, and decoding the plurality of LLR values stored in the plurality of deinterleaving buffers to obtain a second decoding result, the second SCI being contained in a physical sidelink shared channel (PSSCH), and the PSSCH being received based on the first decoding result, and decoding the PSSCH based on the second decoding result.

### CROSS-REFERENCE TO RELATED APPLICATION

This application is based on and claims priority under 35 U.S.C. § 119 to Korean Patent Application No. 10-2023-0138927, filed on Oct. 17, 2023, in the Korean Intellectual Property Office, the disclosure of which is incorporated by reference herein in its entirety.

### BACKGROUND

The inventive concepts relate to a wireless communication device using a plurality of deinterleaving buffers.

New Radio (NR) communication systems may support sidelink-based vehicle-to-everything (V2X) communication. In a sidelink-based V2X communication system, a wireless communication device may receive sidelink control information (SCI) twice. The wireless communication device may obtain control information necessary (or used) for sidelink communication by sequentially decoding received first SCI and second SCI, and decode a physical sidelink shared channel (PSSCH) based on the obtained control information.

When SCI decoding is performed quickly, decoding a PSSCH may also be performed quickly, and thus, the communication speed of the wireless communication device may be improved.

### SUMMARY

The inventive concepts provide a wireless communication device capable of decoding sidelink control information (SCI) more quickly.

According to an aspect of the inventive concepts, there is provided an operation method of a wireless communication device for performing sidelink-based vehicle-to-everything (V2X) communication, the operation method including decoding first sidelink control information (SCI) to obtain a first decoding result, the first SCI being contained in a received physical sidelink control channel (PSCCH), decoding second SCI including obtaining a plurality of log likelihood ratio (LLR) values by demodulating the second SCI, storing the plurality of LLR values in a plurality of deinterleaving buffers such that the plurality of LLR values are deinterleaved, and decoding the plurality of LLR values stored in the plurality of deinterleaving buffers to obtain a second decoding result, the second SCI being contained in a physical sidelink shared channel (PSSCH), and the PSSCH being received based on the first decoding result, and decoding the PSSCH based on the second decoding result.

According to an aspect of the inventive concepts, there is provided a wireless communication device for performing sidelink-based V2X communication, the wireless communication device including a plurality of deinterleaving buffers, and a processing circuitry configured to obtain a plurality of log likelihood ratio (LLR) values by demodulating sidelink control information (SCI), the SCI being contained in a physical sidelink shared channel (PSSCH) sequentially received after a physical sidelink control channel (PSCCH), the PSCCH including first SCI, and the SCI contained in the PSSCH being second SCI, determine a corresponding deinterleaving buffer in which each respective LLR value among the plurality of LLR values is to be stored from among the plurality of deinterleaving buffers such that the plurality of LLR values are deinterleaved, read the plurality of LLR values from the plurality of deinterleaving buffers based on a reading order, and decode the plurality of LLR values according to the reading order.

According to an aspect of the inventive concepts, there is provided an operation method of a wireless communication device for performing sidelink-based V2X communication, the operation method including decoding first sidelink control information (SCI) to obtain a first decoding result, the first SCI being contained in a received physical sidelink control channel (PSCCH), decoding second SCI to obtain a second decoding result, the decoding of the second SCI including obtaining a first log likelihood ratio (LLR) value and a second LLR value by demodulating a first symbol included in the second SCI, storing the first LLR value in a first deinterleaving buffer, and storing the second LLR value in a second deinterleaving buffer, the second SCI being contained in a physical sidelink shared channel (PSSCH), and the PSSCH being received based on the first decoding result, and decoding the PSSCH based on the second decoding result.

### BRIEF DESCRIPTION OF THE DRAWINGS

Embodiments will be more clearly understood from the following detailed description taken in conjunction with the accompanying drawings in which:

FIG. 1 is a diagram illustrating a sidelink-based wireless communication system according to embodiments;

FIG. 2 is a block diagram illustrating a wireless communication device according to embodiments;

FIG. 3 is a diagram illustrating an example of a triangular interleaver structure;

FIGS. 4A and 4B are diagrams illustrating examples of divided triangular interleaver structures used in a wireless communication device, according to embodiments;

FIGS. 5A and 5B are diagrams illustrating examples of a plurality of deinterleaving buffers of a wireless communication device according to embodiments;

FIG. 6 is a flowchart of an operation method of a wireless communication device according to embodiments;

FIG. 7 is a flowchart of a detailed method, performed by a wireless communication device, of decoding first sidelink control information (SCI), according to embodiments;

FIG. 8 is a flowchart of a detailed method, performed by a wireless communication device, of decoding second SCI, according to embodiments;

FIG. 9 is a flowchart of a detailed method, performed by a wireless communication device, of deinterleaving a plurality of log likelihood ratio (LLR) values and storing them in a plurality of deinterleaving buffers and a temporary buffer, according to embodiments; and

FIG. 10 is a block diagram schematically illustrating an electronic device according to embodiments.

### DETAILED DESCRIPTION

A base station refers to an entity that communicates with a wireless communication device and allocates communication network resources to the wireless communication device, and may be at least one of a cell, a base station (BS), a NodeB (NB), an eNodB (eNB), a next-generation radio access network (NG RAN), a radio access unit, a BS controller, a node on a network, a gNodeB (gNB), a transmission and reception point, a transmission point, and/or a remote radio head (RRH).

A wireless communication device refers to an entity that communicates with a BS or other wireless communication devices, and may be referred to as a node, a user equipment (UE), a next-generation UE (NG UE), a mobile station (MS), a mobile equipment (ME), a device, a terminal, or the like.

In addition, the wireless communication device may include at least one of a smart phone, a tablet personal computer (PC), a mobile phone, a video phone, an e-book reader, a desktop PC, a laptop PC, a netbook computer, a personal digital assistant (PDA), a portable multimedia player (PMP), an MP3 player, a medical device, a camera, and/or a wearable device. In addition, the wireless communication device may include at least one of a television, a digital video disc (DVD) player, an audio player, a refrigerator, an air conditioner, a vacuum cleaner, an oven, a microwave oven, a washing machine, an air purifier, a set-top box, a home automation control panel, a security control panel, a media box, a game console, an electronic dictionary, an electronic key, a camcorder, and/or an electronic picture frame. In addition, the wireless communication device may include at least one of various medical devices (e.g., various portable medical measurement devices (e.g., a glucose meter, a heart rate meter, a blood pressure meter, or a body temperature measurement device), a magnetic resonance angiography (MRA) device, a magnetic resonance imaging (MRI) device, a computed tomography (CT) device, an imaging device, or an ultrasonic device), a navigation device, a global navigation satellite system (GNSS), an event data recorder (EDR), a flight data recorder (FDR), an automotive infotainment device, a naval electronic device (e.g., a naval navigation device or a gyrocompass), an avionic electronic device, a security device, an automotive head unit, an industrial or household robot, a drone, an automated teller machine (ATM), a point-of-sales (POS) device, and/or an Internet-of-things (IoT) device (e.g., a bulb, various sensors, a sprinkler device, a fire alarm, a thermostat, a street lamp, a toaster, sporting equipment, a hot-water tank, a heater, and/or a boiler). In addition, the wireless communication device may include various types of multimedia systems for performing communication functions.

Hereinafter, embodiments will be described in detail with reference to the attached drawings.

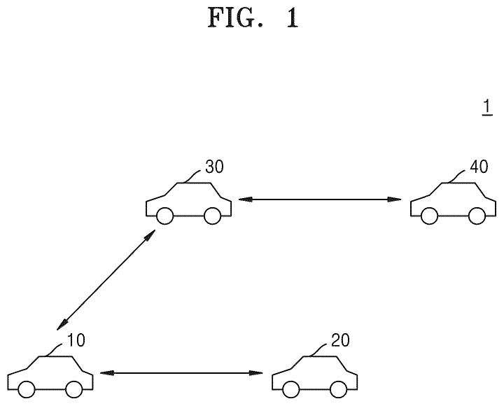

FIG. 1 is a diagram illustrating a sidelink-based wireless communication system according to embodiments.

Referring to FIG. 1, a sidelink-based wireless communication system 1 may be a sidelink-based vehicle-to-everything (V2X) communication system. In a sidelink-based V2X wireless communication system, a wireless communication device may transmit or receive a signal to or from another wireless communication device. That is, the wireless communication device may serve as a transmitting device and/or a receiving device.

The wireless communication system may include first to fourth wireless communication devices 10 to 40.

The first wireless communication device 10 may transmit sidelink signals to other wireless communication devices. For example, the first wireless communication device 10 may transmit sidelink signals to the second and third wireless communication devices 20 and 30. For example, the first wireless communication device 10 may simultaneously (or contemporaneously) transmit signals to the second and third wireless communication devices 20 and 30 by using a wide beam. As another example, the first wireless communication device 10 may transmit signals to the second and third wireless communication devices 20 and 30 by using a plurality of beams. The third wireless communication device 30 may transmit a sidelink signal to the fourth wireless communication device 40. The third wireless communication device 30 may serve as a receiving device in relationship with the first wireless communication device 10, and may serve as a transmitting device in relationship with the fourth wireless communication device 40.

The first wireless communication device 10 may transmit a physical sidelink control channel (PSCCH) and a physical sidelink shared channel (PSSCH) to the second and third wireless communication devices 20 and 30.

The first wireless communication device 10 may transmit sidelink control information (SCI) to other wireless communication devices twice. For example, a first wireless communication device may transmit first SCI and second SCI to other wireless communication devices. The first SCI and the second SCI may include information necessary (or used) for sidelink communication.

The first wireless communication device 10 may transmit a PSCCH including the first SCI to at least one of the second and/or third wireless communication devices 20 and/or 30. The first SCI may include control information such as information related to reception of the second SCI, information related to reception of the PSSCH, channel sensing information, reserved time-frequency resources for transmissions, demodulation reference signal (DMRS) pattern information, and/or DMRS port information.

The second and third wireless communication devices 20 and 30 may decode the first SCI to obtain information related to reception of the second SCI and information related to reception of the PSSCH. In addition, based on the received channel sensing information, the second and third wireless communication devices 20 and 30 may identify whether another wireless communication device is using resources (e.g., time/frequency resources of a communication channel), and determine when to transmit data.

The first wireless communication device 10 may transmit a PSSCH including the second SCI to at least one of the second and third wireless communication devices 20 and 30. The second SCI may include control information such as information related to decoding of the PSSCH, remaining SCI information, remaining scheduling information, and/or targeting receiving (Rx) UE information.

The second and third wireless communication devices 20 and 30 may receive the PSSCH including the second SCI, based on the information related to reception of the second SCI and the information related to reception of the PSSCH that are obtained by decoding the first SCI. Next, the second and third wireless communication devices 20 and 30 may decode the second SCI to obtain information related to decoding of the PSSCH. Here, the second and third wireless communication devices 20 and 30 need to (or may) complete decoding of the second SCI to perform decoding of the PSSCH based on the information related to decoding of the PSSCH that is obtained by decoding the second SCI. Thus, in order for the second and third wireless communication devices 20 and 30 to quickly perform decoding of the PSSCH, decoding of the second SCI needs to (or should) be completed quickly.

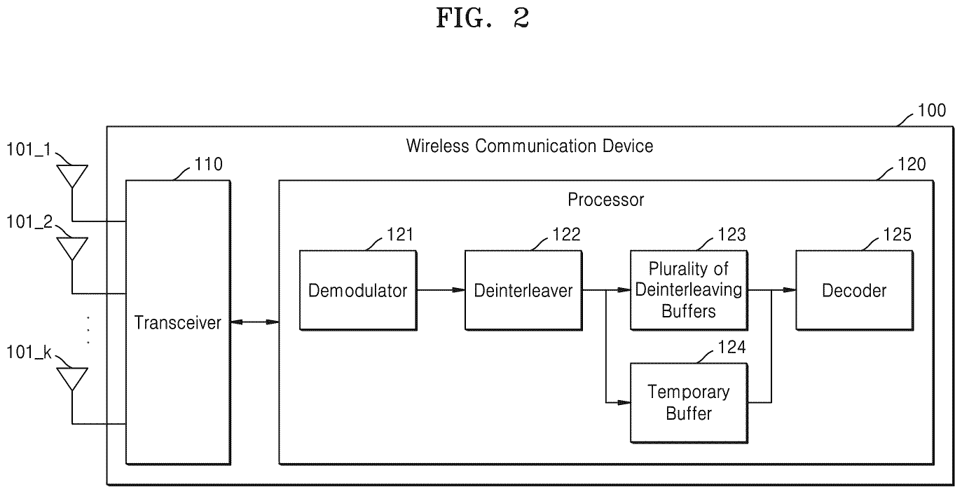

FIG. 2 is a block diagram illustrating a wireless communication device according to embodiments.

Referring to FIG. 2, a wireless communication device 100 according to embodiments may include a plurality of antennas 101_1 to 101_k, a transceiver 110, and/or a processor 120. Here, the wireless communication device 100 illustrated in FIG. 2 may be any one of the first to fourth wireless communication devices 10 to 40 illustrated in FIG. 1.

The transceiver 110 may receive a sidelink signal(s) transmitted from another wireless communication device through the antennas 101_1 to 101_k. The transceiver 110 may receive a PSCCH including first SCI through the sidelink signal(s). In addition, the transceiver 110 may receive a PSSCH including second SCI through the sidelink signal(s). Here, the transceiver 110 may sequentially receive the PSCCH including the first SCI and the PSSCH including the second SCI.

The transceiver 110 may down-convert the frequency of the received sidelink signal to generate an intermediate frequency or baseband signals. In addition, the transceiver 110 may up-convert an intermediate frequency or baseband signals output from the processor 120, and transmit a result of the up-converting as a sidelink signal through the antennas 101_1 to 101_k.

The processor 120 may control the overall communication operation of the wireless communication device 100. The processor 120 may be implemented through a numeric processing unit (NPU), a graphics processing unit (GPU), or the like.

The processor 120 may generate data signals by filtering, decoding, and digitizing an intermediate frequency or baseband signals. The processor 120 may perform a certain operation based on the data signals. In addition, the processor 120 may perform encoding, multiplexing, and conversion to analog on data signals generated through a certain operation.

In embodiments, the processor 120 may sequentially decode the first SCI, the second SCI, and the PSSCH that are received through the sidelink signal. The processor 120 may decode the first SCI, decode the second SCI included in the received PSSCH based on a result of the decoding of the first SCI, and decode the PSSCH based on a result of the decoding of the second SCI.

In embodiments, the processor 120 may include a demodulator 121, a deinterleaver 122, a plurality of deinterleaving buffers 123, and/or a decoder 125. In addition, the processor 120 may further include a temporary buffer 124.

The demodulator 121 may obtain a plurality of log likelihood ratio (LLR) values by demodulating the first SCI. The demodulator 121 may immediately (or promptly) transmit, to the decoder 125, the plurality of LLR values obtained by demodulating the first SCI.

Here, a demodulation method used by the demodulator 121 may be a demodulation method corresponding to a modulation method (e.g., a modulation type/scheme and/or demodulation type/scheme) agreed to be used (or previously signaled) in the wireless communication system 1, and may be, for example, any one of quadrature phase-shift keying (QPSK), 16-quadrature amplitude modulation (QAM), 64-QAM, 256-QAM, or the like.

The first SCI may include a plurality of symbols. The demodulator 121 may obtain a plurality of LLR values by demodulating the plurality of symbols included in the first SCI, respectively. Here, the relationship between the number of symbols and the number of LLR values may vary depending on the demodulation method. For example, in a case in which the demodulation method used by the demodulator 121 is QPSK, the demodulator 121 may obtain two LLR values by demodulating one symbol, and thus, the number of the plurality of LLR values may be twice the number of the plurality of symbols.

In addition, the demodulator 121 may obtain a plurality of LLR values by demodulating the second SCI. The demodulator 121 may transmit, to the deinterleaver 122, the plurality of LLR values obtained by demodulating the second SCI.

Hereinafter, unless it is specified from which of the first SCI and the second SCI the plurality of LLR values are obtained by demodulating, the plurality of LLR values are obtained by demodulating the second SCI.

The second SCI may include a plurality of symbols. The demodulator 121 may obtain a plurality of LLR values by demodulating the plurality of symbols included in the second SCI, respectively. Here, the relationship between the number of the plurality of symbols and the number of the plurality of LLR values may be the same as (or similar to) in the first SCI described above.

Here, in a case in which the demodulation method used by the demodulator 121 is QPSK, the demodulator 121 may simultaneously (or contemporaneously) transmit, to the deinterleaver 122, two LLR values generated by demodulating one symbol. That is, the demodulator 121 may simultaneously (or contemporaneously) transmit, to the deinterleaver 122, multiple LLR values generated by demodulating one symbol.

In addition, the demodulator 121 may transmit a plurality of LLR values to the deinterleaver 122 in the order in which the plurality of symbols are demodulated. For example, in a case in which the demodulation method used by the demodulator 121 is QPSK, the demodulator 121 may sequentially demodulate first to n-th symbols (n is a natural number greater than or equal to 2) to obtain first to (2*n)-th LLR values two at a time, and transmit them to the deinterleaver 122 two at a time (e.g., simultaneously or contemporaneously). That is, the demodulator 121 may transmit, to the deinterleaver 122, first and second LLR values obtained by demodulating a first symbol, and then transmit, to the deinterleaver 122, third and fourth LLR values obtained by demodulating a second symbol. Then, the demodulator 121 may sequentially transmit, to the deinterleaver 122, fifth to (2*n)-th LLR values obtained by sequentially demodulating third to n-th symbols.

The deinterleaver 122 may receive the plurality of LLR values obtained by demodulating the second SCI. The deinterleaver 122 may store the plurality of LLR values in the plurality of deinterleaving buffers 123 such that the plurality of received LLR values are deinterleaved.

Here, a deinterleaving method used by the deinterleaver 122 may be a deinterleaving method corresponding to an interleaving method agreed to be used (or previously signaled) in the wireless communication system 1.

In more detail, the deinterleaver 122 may determine a deinterleaving buffer in which each of the plurality of LLR values obtained by demodulating the second SCI is to be stored, from among the plurality of deinterleaving buffers 123 such that the plurality of LLR values are deinterleaved.

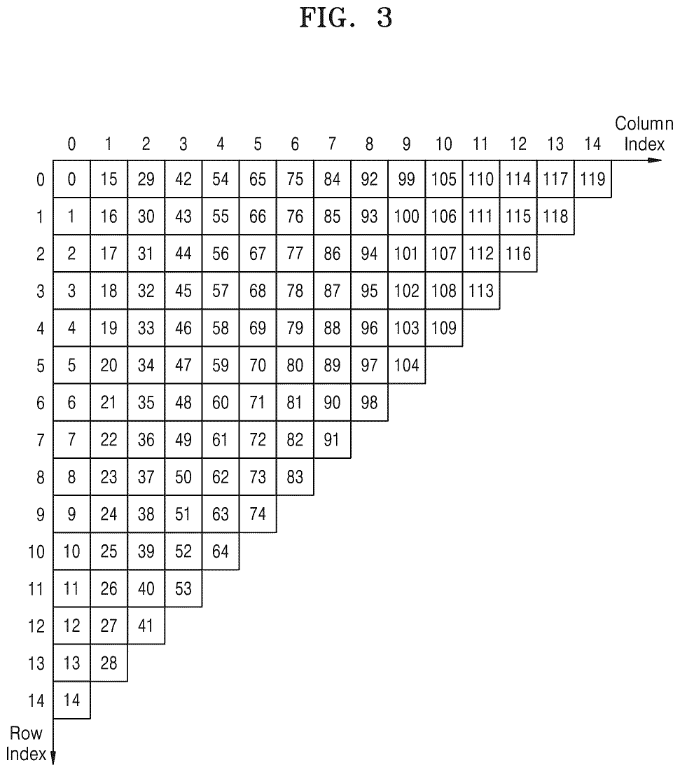

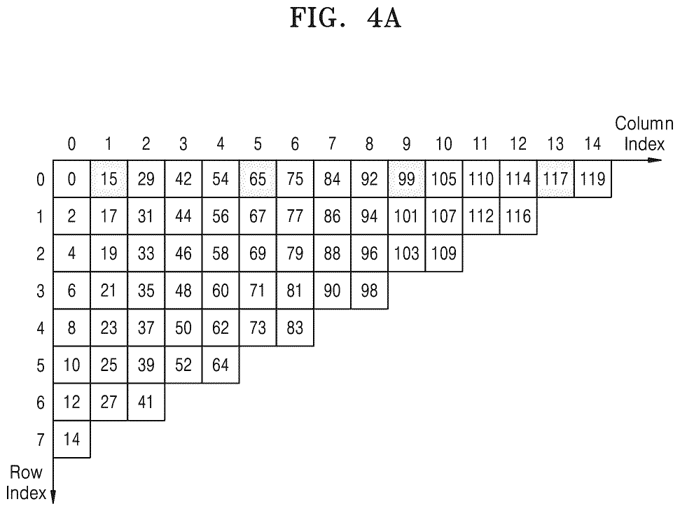

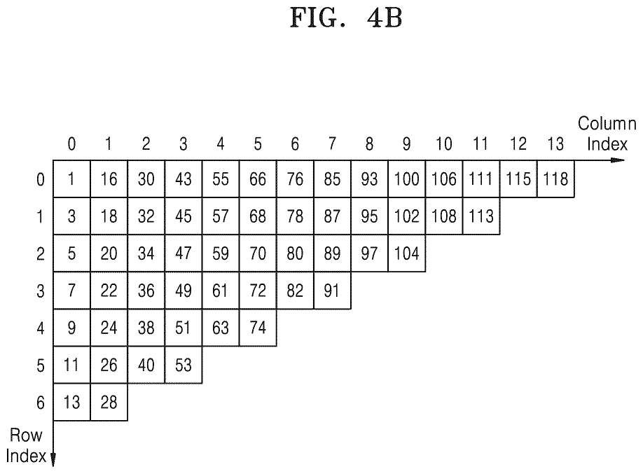

In embodiments, the deinterleaver 122 may determine a deinterleaving buffer in which each of the plurality of LLR values is to be stored, from among the plurality of deinterleaving buffers 123, such that the plurality of LLR values are deinterleaved based on divided triangular interleaver structures. Here, a triangular interleaver structure and divided triangular interleaver structures may be described in more detail with reference to FIGS. 3, 4A, and 4B.

FIG. 3 is a diagram illustrating an example of a triangular interleaver structure.

FIG. 3 illustrates an example of a commonly used triangular interleaver structure. Each area in the triangular interleaver structure may be identified by a row index and a column index. Here, the number written in each area in the triangular interleaver may be an index of each of the plurality of LLR values. Hereinafter, the (a, b) area may represent an area in the triangular interleaver of which the row index is a and the column index is b.

When a plurality of LLR values are written in a triangular interleaver, the plurality of LLR values may be written in the column direction. For example, the plurality of LLR values may be written while incrementing the row index and maintaining the column index, and when the row index may no longer be incremented, incrementing the column index.

In the example of FIG. 3, when the plurality of LLR values are sequentially written in the triangular interleaver from the LLR value with an index of 0 to the LLR value with an index of 119, the LLR values with indices 0 to 14 may be sequentially written from the (0, 0) area to the (14, 0) area while incrementing the row index and maintaining the column index. Here, because it is impossible to increment the row index (e.g., because the final row index in the present column has been reached) after an LLR value is written in the (14, 0) area, the column index is incremented and then the LLR values with indices 15 to 28 may be sequentially written while incrementing the row index and maintaining the column index, from the (0, 1) area to the (13, 1) area. By repeating this process, the plurality of LLR values may all be written in the triangular interleaver.

Next, when the plurality of LLR values are read from the triangular interleaver, the plurality of LLR values may be read in the row direction. For example, the plurality of LLR values may be read while incrementing the column index and maintaining the row index, and when the column index may no longer be incremented, incrementing the row index.

In the example of FIG. 3, when the plurality of LLR values are read from the triangular interleaver, the LLR values with indices 0, 15, 29, . . . , 119 may be sequentially read while incrementing the column index and maintaining the row index, from the (0, 0) area to the (0, 14) area. Here, because it is impossible to increment the column index (e.g., because the final column index in the present row has been reached) after an LLR value is read from the (0, 14) area, the row index is incremented and then the LLR values with indices 1, 16, 30, . . . , 118 may be sequentially read while incrementing the column index and maintaining the row index, from the (1, 0) area to the (1, 13) area. By repeating this process, the plurality of LLR values may all be read from the triangular interleaver.

As such, the order of the plurality of LLR values may be changed by differentiating the direction of writing the plurality of LLR values in the triangular interleaver and the direction of reading the plurality of LLR values from the triangular interleaver. Here, changing the original order of the plurality of LLR values may be referred to as interleaving, and returning the changed order of the plurality of LLR values to the original order may be referred to as deinterleaving.

Here, in a case in which the deinterleaver 122 uses the triangular interleaver structure as illustrated in FIG. 3, even when the deinterleaver 122 receives, from the demodulator 121, multiple LLR values generated by demodulating one symbol, the deinterleaver 122 is able to process one LLR value at a time, and thus, the overall processing time of the deinterleaver 122 may increase. In order to improve this issue, according to the inventive concepts, divided triangular interleaver structures as illustrated in FIGS. 4A and 4B may be used.

FIGS. 4A and 4B are diagrams illustrating examples of divided triangular interleaver structures used in a wireless communication device, according to embodiments.

FIGS. 4A and 4B illustrate examples of divided triangular interleaver structures according to embodiments. The example of FIGS. 4A and 4B corresponds to divided triangular interleaver structures used in a case in which two LLR values are generated by demodulating one symbol as in QPSK, in which case, two LLR values are generated and thus two divided triangular interleaver structures may be used. On the contrary, in a case in which four LLR values are generated by demodulating one symbol as in 16-QAM, four divided triangular interleaver structures may be used, and similarly, divided triangular interleaver structures may be used for other demodulation methods.

Hereinafter, for convenience of description, the divided triangular interleaver structure illustrated in FIG. 4A will be referred to as a first divided triangular interleaver structure, and the divided triangular interleaver structure illustrated in FIG. 4B will be referred to as a second divided triangular interleaver structure.

The directions in which the plurality of LLR values are written in and read from the first and second divided triangular interleaver structures may be the same as (or similar to) the directions in which the plurality of LLR values are written in and read from the triangular interleaver structure (e.g., from the triangle interleaver structure of FIG. 3).

The first divided triangular interleaver structure may include the areas with even row indices in the triangular interleaver structure of FIG. 3. That is, the areas with row indices of 0 to 7 in the first divided triangular interleaver structure may correspond to the areas with row indices of 0, 2, 4, . . . , 14 in the triangular interleaver structure of FIG. 3, respectively. In addition, the second divided triangular interleaver structure may include the areas with odd row indices in the triangular interleaver structure of FIG. 3. That is, the areas with row indices of 0 to 6 in the second divided triangular interleaver structure may correspond to the areas with row indices of 1, 3, 5, . . . , 13 in the triangular interleaver structure of FIG. 3, respectively.

Here, in a case in which the deinterleaver 122 uses the divided triangular interleaver structures as illustrated in FIGS. 4A and 4B, even when the deinterleaver 122 receives, from the demodulator 121, multiple LLR values generated by demodulating one symbol, the deinterleaver 122 is able to process multiple LLR values at a time (e.g., simultaneously or contemporaneously), and thus, the overall processing time of the deinterleaver 122 may be reduced.

For example, in a case in which the demodulation method is QPSK, the demodulator 121 may demodulate a first symbol included in the second SCI to obtain a first LLR value (e.g., an LLR value with an index of 0) and a second LLR value (e.g., an LLR value with an index of 1), and transmit the first and second LLR values to the deinterleaver 122. Here, the deinterleaver 122 may process the first LLR value through the first divided triangular interleaver structure and the second LLR value through the second divided triangular interleaver structure, and thus, the overall processing time of the deinterleaver 122 may be reduced. According to embodiments, the demodulator 121 may associate each LLR value among the plurality of LLR values with a corresponding index. The corresponding index may have an integer value that increments (by one) with each obtained LLR value (starting at an index of zero).

Referring back to FIG. 2, the deinterleaver 122 may determine a deinterleaving buffer in which each of the plurality of LLR values is to be stored, from among the plurality of deinterleaving buffers 123, based on the divided triangular interleaver structures and the indices of the plurality of LLR values.

In a case in which the demodulation method is QPSK, the deinterleaver 122 may determine a deinterleaving buffer in which each of the plurality of LLR values is to be stored, by using the first and second divided triangular interleaver structures as illustrated in FIGS. 4A and 4B. Here, it may be preset (or alternatively, given) which of the first and second divided triangular interleaver structures is to be used for processing the plurality of LLR values, according to the indices of the plurality of LLR values. For example, because the first LLR value has an index of 0 and is thus processed by using the first divided triangular interleaver structure, the first deinterleaving buffer may be determined as the deinterleaving buffer in which the first LLR value is to be stored. In addition, because the second LLR value has an index of 1 and is thus processed by using the second divided triangular interleaver structure, the second deinterleaving buffer may be determined as the deinterleaving buffer in which the second LLR value is to be stored. As such, the deinterleaver 122 may determine a deinterleaving buffer in which each of the plurality of LLR values is to be stored, based on the indices of the plurality of LLR values included in the divided triangular interleaver structures. According to embodiments, for example, each of the plurality of deinterleaving buffers 123 may respectively correspond to a different one of the divided triangular interleaver structures.

The deinterleaver 122 may transmit the plurality of LLR values to the plurality of deinterleaving buffers 123 based on a result of determining a deinterleaving buffer in which each of the plurality of LLR values is to be stored, so as to store the plurality of LLR values in the plurality of deinterleaving buffers 123 such that the plurality of LLR values are deinterleaved.

In addition, when the deinterleaver 122 determines that LLR values included in the same LLR value group (or similar LLR value groups) are to be stored in the same deinterleaving buffer (or similar deinterleaving buffers) among the plurality of deinterleaving buffers 123, the deinterleaver 122 may determine that at least one of the LLR values included in the same LLR value group (or similar LLR value groups) is to be stored in the temporary buffer 124.

Here, an LLR value group may include a plurality of LLR values that are obtained through demodulation of the same symbol (or similar symbols). That is, each of the plurality of LLR values and one or more other LLR values that are obtained through demodulation of the same symbol (or similar symbols) by the demodulator 121 may be included in the same LLR value group (or similar LLR value groups). For example, in a case in which the demodulation method is QPSK, the first and second LLR values that are generated by demodulating the first symbol may be included in the same LLR value group (or similar LLR value groups).

A plurality of LLR values included in the same LLR value group (or similar LLR value groups) may be simultaneously (or contemporaneously) transmitted to the deinterleaver 122 through the demodulator 121. Here, when the LLR values included in the same LLR value group (or similar LLR value groups) are stored in the same deinterleaving buffer (or similar deinterleaving buffers) among the plurality of deinterleaving buffers 123, it may be impossible (or difficult) to simultaneously (or contemporaneously) store the LLR values included in the same LLR value group (or similar LLR value groups), in a plurality of deinterleaving buffers.

For example, in a case in which the divided triangular interleaver structures as illustrated in FIGS. 4A and 4B are used, a 15th LLR value (e.g., an LLR value with an index of 14) and a 16th LLR value (e.g., an LLR value with an index of 15), which are generated by demodulating an eighth symbol included in the second SCI, may all be processed through the first divided triangular interleaver structure, and determined to be stored in the first deinterleaving buffer.

As such, when it is determined that the LLR values included in the same LLR value group (or similar LLR value groups) are stored (or are to be stored) in the same deinterleaving buffer (or similar deinterleaving buffers), the deinterleaver 122 may determine that at least one of the LLR values included in the same LLR value group (or similar LLR value groups) is to be stored in the temporary buffer 124. According to embodiments, the deinterleaver 112 may determine areas of the divided triangular interleaver structures to which the plurality of LLR values are to be written (e.g., stored) in the column direction according to the indices of the plurality of LLR values as discussed above. The deinterleaver 112 may determine that at least one of the LLR values included in the same LLR value group (or similar LLR value groups) is to be stored in the temporary buffer 124, instead of a deinterleaving buffer among the plurality of deinterleaving buffers 123, based on (e.g., in response to) determining that two or more of the LLR values included in the same LLR value group (or similar LLR value groups) would be written (e.g., stored) in the same deinterleaving buffer (or similar deinterleaving buffers) according to the column direction-based assignment of areas and the respective forms of the divided triangular interleaver structures. For example, the deinterleaver 122 may determine that the 16th LLR value among the 15th and 16th LLR values is to be stored in the temporary buffer 124.

Similarly, in a case in which the divided triangular interleaver structures as illustrated in FIGS. 4A and 4B, the deinterleaver 122 may determine that the 16th LLR value (e.g., an LLR value with an index of 15), a 66th LLR value (e.g., an LLR value with an index of 65), a 100th LLR value (e.g., an LLR value with an index of 99), and a 118th LLR value (e.g., an LLR value with an index of 117), which are shaded with dots, are to be stored in the temporary buffer 124.

Here, the LLR values determined to be stored in the temporary buffer 124 may not be stored in the plurality of deinterleaving buffers 123.

By using the temporary buffer 124 as described above, LLR values included in the same LLR value group (or similar LLR value groups) are prevented from being stored in the same deinterleaving buffer (or similar deinterleaving buffer), and/or the occurrence of the same is reduced, and thus, the speed of decoding SCI may be increased.

In addition, the deinterleaver 122 may determine, based on the number of LLR values included in a reading-direction line according to the divided triangular interleaver structures, an address at which each of the plurality of LLR values is to be stored in the plurality of deinterleaving buffers 123. According to embodiments, for example, the deinterleaver 112 may determine areas of the divided triangular interleaver structures to which the plurality of LLR values are to be written (e.g., stored) in the column direction according to the indices of the plurality of LLR values as discussed above. The deinterleaver 122 may determine a respective address for each of the areas to which the LLR values are to be written (e.g., stored) and values for the respective addresses may be based on the number of LLR values included in a reading-direction line of the divided triangular interleaver structures. For example, values of the addresses of the areas may start at zero in a first column and a first row of each divided triangular interleaver structure, and increment (e.g., by one) for each column index along a first row. After the last column of the first row, the value of the address of the first column of the next row may be an increment higher than the last column of the first row, and the values of the addresses may increment (e.g., by one) for each column index along the second row, and so forth along the reading order (e.g., the row direction as discussed above) of the areas of the divided triangular interleaver structures.

In order to enable the decoder 125, which will be described below, to read a plurality of LLR values in an address order from the plurality of deinterleaving buffers 123, the deinterleaver 122 may determine an address at which each of the plurality of LLR values is to be stored in the plurality of deinterleaving buffers 123.

For example, in a case in which the demodulation method is QPSK, a third LLR value (e.g., an LLR value with an index of 2) generated by demodulating the second symbol is stored in the first deinterleaving buffer by the deinterleaver 122, but when it is stored at a second address of the first deinterleaving buffer, the decoder 125 may be unable to read the plurality of LLR values from the plurality of deinterleaving buffers 123 in the address order. An address at which the third LLR value is to be stored in the first deinterleaving buffer may be determined based on the number of LLR values that need to (or that are to) be read prior to the third LLR value on a row-direction line, which is a reading-direction line, in the first divided triangular interleaver structure as illustrated in FIG. 4A. In the first divided triangular interleaver structure as illustrated in FIG. 4A, the address at which the third LLR value is to be stored in the first deinterleaving buffer may be determined to be a 16th address of the first deinterleaving buffer.

Each of the plurality of deinterleaving buffers 123 may store at least some of the plurality of LLR values. Here, the number of the plurality of deinterleaving buffers 123 may be set based on a method of demodulating the second SCI. For example, in a case in which two LLR values are generated by demodulating one symbol as in QPSK, the number of the plurality of deinterleaving buffers 123 may be two. As another example, in a case in which four LLR values are generated by demodulating one symbol as in 16-QAM, the number of the plurality of deinterleaving buffers 123 may be four.

Here, each of the plurality of deinterleaving buffers 123 may store at least some of the plurality of LLR values based on a result of determining, by the deinterleaver 122, a deinterleaving buffer in which each of the plurality of LLR values is to be stored, and a result of determining, by the deinterleaver 122, an address at which each of the plurality of LLR values is to be stored in the plurality of deinterleaving buffers 123. That is, the plurality of deinterleaving buffers 123 may store the plurality of LLR values based on the index of a deinterleaving buffer in which an LLR value received from the deinterleaver 122 is to be stored, and an address in the deinterleaving buffer.

The temporary buffer 124 may store one or more LLR values that are not stored in the plurality of deinterleaving buffers 123, among the plurality of LLR values. That is, the temporary buffer 124 may store LLR values that are determined not to be stored in the plurality of deinterleaving buffers 123 but to be stored in the temporary buffer 124 (e.g., are to be stored in the temporary buffer 124 instead of in the plurality of deinterleaving buffers 123), as the deinterleaver 122 determines that LLR values included in the same LLR value group (or similar LLR value groups) are to be stored in the same deinterleaving buffer (or similar deinterleaving buffers) among the plurality of deinterleaving buffers 123 (e.g., the deinterleaver 122 may store an LLR value in the temporary buffer 124 instead of in the plurality of deinterleaving buffers 123 in response to determining that the LLR value would otherwise be stored in the same deinterleaving buffer, or a similar deinterleaving buffer, with at least one other LLR value from the same LLR value group, or a similar LLR value group).

The decoder 125 may decode the plurality of LLR values obtained by demodulating the first SCI. The decoder 125 may decode the plurality of LLR values obtained by demodulating the first SCI, by sequentially perform descrambling, rate matching, and/or decoding using a preset (or alternatively, given) decoding method (e.g., a polar decoding method) on the plurality of LLR values.

In addition, the decoder 125 may decode the plurality of LLR values obtained by demodulating the second SCI that are stored in the plurality of deinterleaving buffers 123.

The decoder 125 may read the plurality of LLR values from the plurality of deinterleaving buffers 123 based on a preset (or alternatively, given) reading order (e.g., the row direction as discussed above).

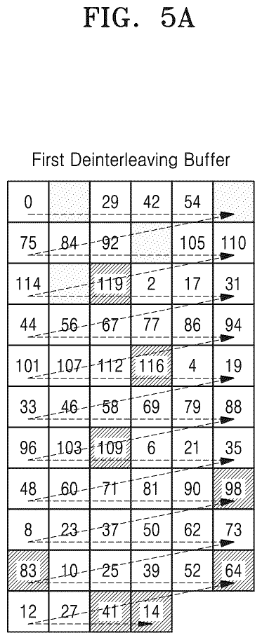

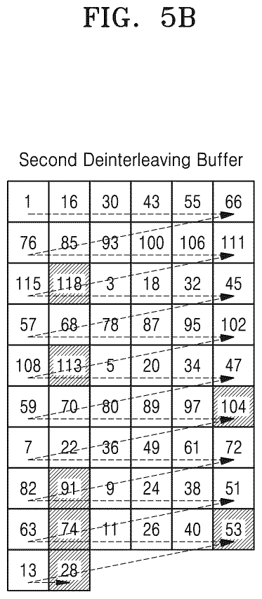

The reading order may be set such that the number of LLR values read at a time (e.g., simultaneously or contemporaneously) from the plurality of deinterleaving buffers decreases, and a plurality of LLR values are read alternately from the plurality of deinterleaving buffers. The reading order may be described in more detail with reference to FIGS. 5A and 5B illustrating examples of the plurality of deinterleaving buffers 123.

FIGS. 5A and 5B are diagrams illustrating examples of a plurality of deinterleaving buffers of a wireless communication device according to embodiments.

FIGS. 5A and 5B illustrate examples of structures of a plurality of deinterleaving buffers according to embodiments. In the examples of FIGS. 5A and 5B, two LLR values may be generated by demodulating one symbol as in QPSK, and thus, two deinterleaving buffers may be used. However, on the contrary, in a case in which four LLR values are generated by demodulating one symbol as in 16-QAM, four deinterleaving buffers may be used.

First, referring to FIG. 5A, it may be seen that some of a plurality of LLR values are written in a first deinterleaving buffer based on a first divided triangular deinterleaver structure as illustrated in FIG. 4A. Here, an address at which no LLR value is stored in the first deinterleaving buffer may be an address at which no LLR value is stored as (e.g., because) it is determined that LLR values included in the same LLR value group (or similar LLR value groups) are all to be stored in a first interleaving buffer, and thus one of them is stored in the temporary buffer 124.

In addition, referring to FIG. 5B, it may be seen that some of a plurality of LLR values are written in a second deinterleaving buffer based on a second divided triangular deinterleaver structure as illustrated in FIG. 4B.

In a case in which LLR values are stored in the first and second deinterleaving buffers as illustrated in FIGS. 5A and 5B described above, the decoder 125 may read one or more LLR values alternately from the first and second deinterleaving buffers. Here, the number of LLR values that the decoder 125 reads from the first and second deinterleaving buffers at a time may decrease.

For example, first, the decoder 125 may sequentially read 15 LLR values (e.g., the number of columns in the first row of the first divided triangular deinterleaver structure as illustrated in FIG. 4A) from the first deinterleaving buffer in the direction indicated by dotted arrows in FIG. 5A (e.g., incrementing columns in a row, then incrementing the row once the all of the columns in a row have been read, and so on). Then, the decoder 125 may sequentially read 14 LLR values (e.g., the number of columns in the first row of the second divided triangular deinterleaver structure as illustrated in FIG. 4B) from the second deinterleaving buffer in the direction indicated by dotted arrows in FIG. 5B (e.g., incrementing columns in a row, then incrementing the row once the all of the columns in a row have been read, and so on). Then, the decoder 125 may sequentially read 13 LLR values (e.g., the number of columns in the second row of the first divided triangular deinterleaver structure as illustrated in FIG. 4A) from the first deinterleaving buffer, and sequentially read 12 LLR values (e.g., the number of columns in the second row of the second divided triangular deinterleaver structure as illustrated in FIG. 4B) from the second deinterleaving buffer. By repeating this method, finally, the decoder 125 may sequentially read two LLR values from the second deinterleaving buffer, and read the last one LLR value from the first deinterleaving buffer.

That is, the decoder 125 may read one or more LLR values in the direction indicated by the dotted arrows in FIGS. 5A and 5B, but may only read up to an LLR value stored in a slash-shaded area at a time.

Here, when the decoder 125 reads a plurality of LLR values from the plurality of deinterleaving buffers 123 based on the reading order, and no LLR values are stored in the plurality of deinterleaving buffers, the decoder 125 may read an LLR value from the temporary buffer 124. For example, when the decoder 125 needs to (or is to) read an LLR value from the second address of the first deinterleaving buffer, and no LLR value exists at the second address of the first deinterleaving buffer, the decoder 125 may read a corresponding LLR value from the temporary buffer 124.

Referring back to FIG. 2, the decoder 125 may decode a plurality of LLR values listed (e.g., read out) in the reading order (e.g., in the order in which the LLR values are read from the divided triangular interleaver structures). In embodiments, the decoder 125 may decode the plurality of LLR values by sequentially performing rate matching and decoding using a preset (or alternatively, given) decoding method (e.g., a polar decoding method) on the plurality of LLR values listed in the reading order.

The wireless communication device 100 according to the inventive concepts as described above may store a plurality of LLR values in the plurality of deinterleaving buffers 123 and the temporary buffer 124 based on divided triangular interleaver structures, and read and decode the plurality of LLR values from the plurality of deinterleaving buffers 123 and the temporary buffer 124, thereby increasing the speed of decoding second SCI and thus improving the communication speed of the wireless communication device 100.

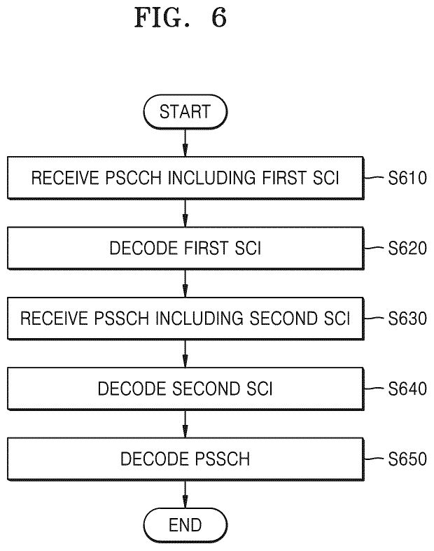

FIG. 6 is a flowchart of an operation method of a wireless communication device according to embodiments.

Referring to FIG. 6, in operation S610, the wireless communication device 100 may receive a PSCCH including first SCI. The wireless communication device 100 may receive the PSCCH including the first SCI by receiving a sidelink signal transmitted from another wireless communication device through the transceiver 110.

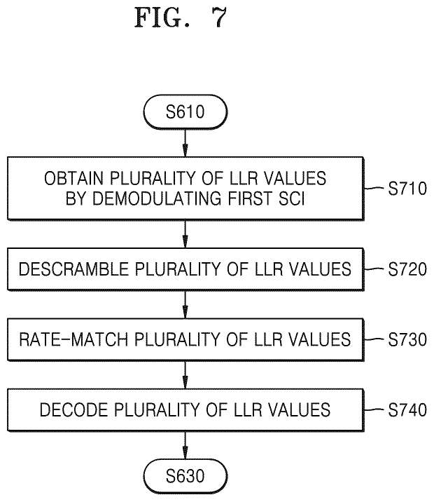

In operation S620, the wireless communication device 100 may decode the first SCI. The wireless communication device 100 may obtain information related to reception of second SCI, information related to reception of a PSSCH, and the like, by decoding the first SCI through the processor 120. More detailed operations in which the wireless communication device 100 decodes the first SCI will be described below with reference to FIG. 7.

In operation S630, the wireless communication device 100 may receive the PSSCH including the second SCI. The wireless communication device 100 may receive the PSSCH including the second SCI by receiving a sidelink signal transmitted from another wireless communication device through the transceiver 110 based on the information related to reception of the second SCI and information related to reception of the PSSCH that are obtained by decoding the first SCI.

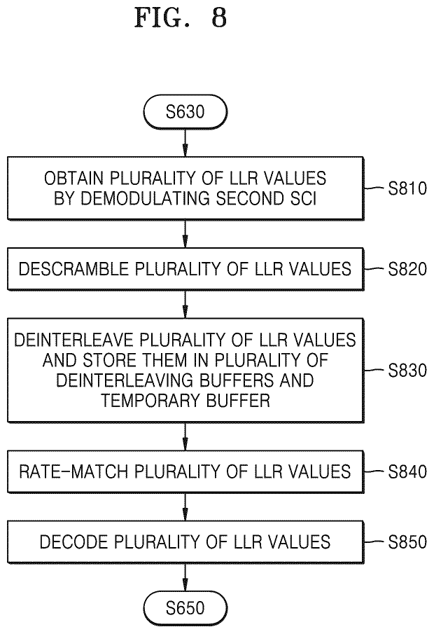

In operation S640, the wireless communication device 100 may decode the second SCI. The wireless communication device 100 may obtain information related to decoding of the PSSCH, by decoding the second SCI through the processor 120. More detailed operations in which the wireless communication device 100 decodes the second SCI will be described below with reference to FIG. 8.

In operation S650, the wireless communication device 100 may decode the PSSCH. The wireless communication device 100 may decode the PSSCH based on the information related to decoding of the PSSCH obtained by decoding the second SCI through the processor 120. According to embodiments, the wireless communication device 100 may recover a data signal (e.g., a data signal sent through the PSSCH by, for example, another wireless communication device 100). The wireless communication device 100 may perform further processing on the data signal, provide the data signal to an application program 1013 for use by the application program 1013 in performing a process, provide the data signal to a display unit 1050 to be output thereby, etc. According to embodiments, the wireless communication device 100 may generate a response data signal based on (e.g., in response to) the recovered data signal and transmit the response data signal to an external device (e.g., another wireless communication device 100, such as the wireless communication device 100 that sent the data signal) via, for example, a sidelink signal for V2X communication.

FIG. 7 is a flowchart of a detailed method, performed by a wireless communication device, of decoding first SCI, according to embodiments.

Referring to FIG. 7, in operation S710, the wireless communication device 100 may obtain a plurality of LLR values by demodulating the first SCI through the processor 120. The processor 120 may demodulate the first SCI through the demodulator 121.

In operation S720, the processor 120 may descramble the plurality of LLR values obtained by demodulating the first SCI. The processor 120 may descramble the plurality of LLR values obtained by demodulating the first SCI, through the decoder 125. In embodiments, as the processor 120 descrambles the plurality of LLR values obtained by demodulating the first SCI, sign bits of the plurality of LLR values obtained by demodulating the first SCI may be changed.

In operation S730, the processor 120 may rate-match the plurality of LLR values obtained by demodulating the first SCI. The processor 120 may rate-match the plurality of descrambled LLR values obtained by demodulating the first SCI through the decoder 125.

In operation S740, the processor 120 may decode the plurality of LLR values obtained by demodulating the first SCI. The processor 120 may decode the plurality of rate-matched LLR values obtained by demodulating the first SCI through the decoder 125, by using a preset (or alternatively, given) decoding method (e.g., a polar decoding method). As such, the processor 120 may obtain the information related to reception of the second SCI, the information related to reception of the PSSCH, and the like, by decoding the plurality of LLR values obtained by demodulating the first SCI.

FIG. 8 is a flowchart of a detailed method, performed by a wireless communication device, of decoding second SCI, according to embodiments.

Referring to FIG. 8, in operation S810, the wireless communication device 100 may obtain a plurality of LLR values by demodulating the second SCI through the processor 120. The processor 120 may demodulate the second SCI through the demodulator 121.

In operation S820, the processor 120 may descramble the plurality of LLR values. The processor 120 may descramble the plurality of LLR values through a separate descrambler (not shown). In embodiments, as the processor 120 descrambles the plurality of LLR values, sign bits of the plurality of LLR values may be changed.

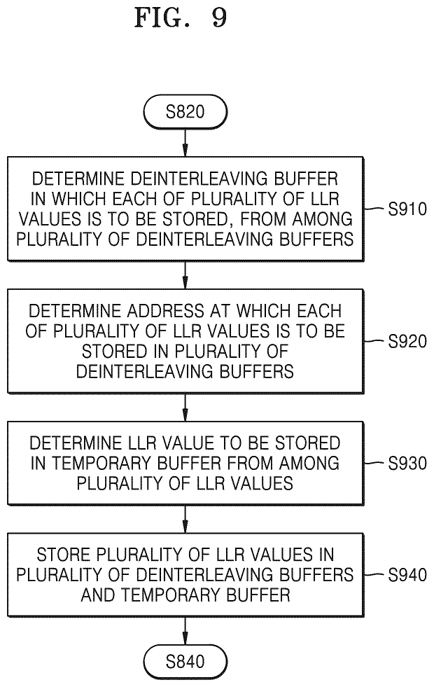

In operation S830, the processor 120 may deinterleave the plurality of LLR values and store them in the plurality of deinterleaving buffers 123 and the temporary buffer 124. The processor 120 may store the plurality of descrambled LLR values in the plurality of deinterleaving buffers 123 and the temporary buffer 124, to be deinterleaved through the deinterleaver 122 based on divided triangular interleaver structures. More detailed operations in which the wireless communication device 100 deinterleaves the plurality of LLR values and storing them in the plurality of deinterleaving buffers 123 and the temporary buffer 124 will be described below with reference to FIG. 9.

In operation S840, the processor 120 may rate-match the plurality of LLR values. The processor 120 may read the plurality of LLR values from the plurality of deinterleaving buffers 123 and the temporary buffer 124 through the decoder 125 based on the reading order. Then, the processor 120 may rate-match the plurality of LLR values listed in the reading order through the decoder 125.

In operation S850, the processor 120 may decode the plurality of LLR values. The processor 120 may decode the plurality of rate-matched LLR values through the decoder 125 by using a preset (or alternatively, given) decoding method (e.g., a polar decoding method). As such, the processor 120 may obtain the information related to decoding of the PSSCH, by decoding the plurality of LLR values obtained by demodulating the second SCI.

FIG. 9 is a flowchart of a detailed method, performed by a wireless communication device, of deinterleaving a plurality of LLR values and storing them in a plurality of deinterleaving buffers and a temporary buffer, according to embodiments.

Referring to FIG. 9, in operation S910, the processor 120 may determine a deinterleaving buffer in which each of the plurality of LLR values is to be stored, from among the plurality of deinterleaving buffers 123. The processor 120 may determine, through the deinterleaver 122, a deinterleaving buffer in which each of the plurality of LLR values is to be stored, from among the plurality of deinterleaving buffers 123, based on divided triangular interleaver structures and the indices of the plurality of LLR values.

In operation S920, the processor 120 may determine an address at which each of the plurality of LLR values is to be stored in the plurality of deinterleaving buffers 123. The processor 120 may determine, through the deinterleaver 122, an address at which each of the plurality of LLR values is to be stored in the plurality of deinterleaving buffers 123, based on the number of LLR values included in a reading-direction line according to the divided triangular interleaver structures.

In operation S930, the processor 120 may determine an LLR value to be stored in the temporary buffer 124 from among the plurality of LLR values. In addition, when it is determined that LLR values included in the same LLR value group (or similar LLR value groups) are to be stored in the same deinterleaving buffer (or similar deinterleaving buffers), the processor 120 may determine, through the deinterleaver 122, that at least one of the LLR values included in the same LLR value group (or similar LLR value groups) is to be stored in the temporary buffer 124.

In operation S940, the processor 120 may store the plurality of LLR values in the plurality of deinterleaving buffers 123 and the temporary buffer 124. The processor 120 may store the plurality of LLR values in the plurality of deinterleaving buffers 123 and the temporary buffer 124, based on the index of the deinterleaving buffer in which the LLR value is to be stored and the address in the deinterleaving buffer that are previously determined, through the deinterleaver 122, and whether to store an LLR value in the temporary buffer 124.

The operation method of the wireless communication device 100 according to the inventive concepts as described above may store a plurality of LLR values in the plurality of deinterleaving buffers 123 and the temporary buffer 124 based on divided triangular interleaver structures, and read and decode the plurality of LLR values from the plurality of deinterleaving buffers 123 and the temporary buffer 124, thereby increasing the speed of decoding second SCI and thus improving the communication speed of the wireless communication device.

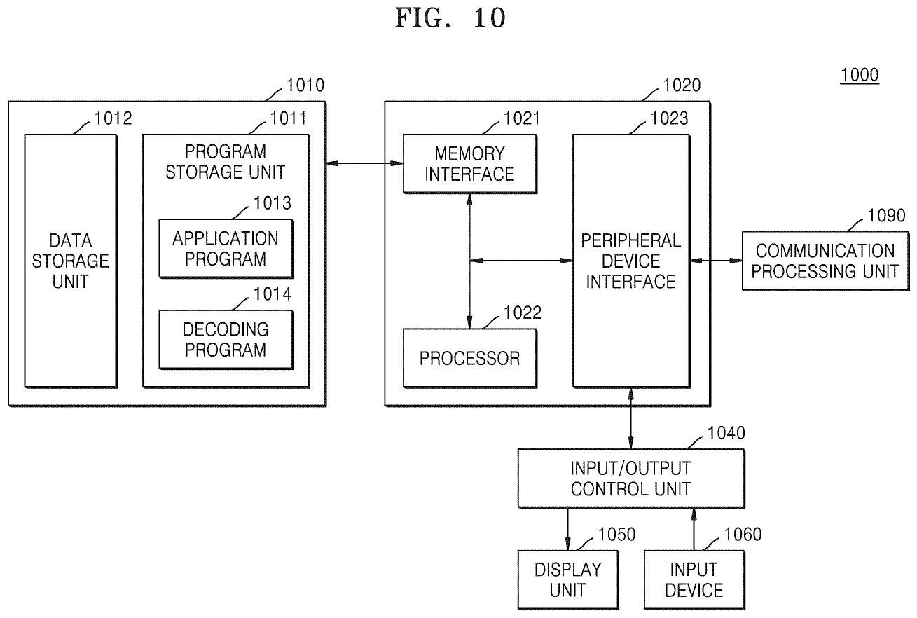

FIG. 10 is a block diagram schematically illustrating an electronic device according to embodiments.

Referring to FIG. 10, an electronic device 1000 may include a memory 1010, a processor unit 1020, an input/output control unit 1040, a display unit 1050, an input device 1060, and/or a communication processing unit 1090. Here, a plurality of memories 1010 may be provided. Hereinafter, each component will be described.

The memory 1010 may include a program storage unit 1011 for storing a program for controlling the operation of the electronic device, and a data storage unit 1012 for storing data generated during execution of the program. The data storage unit 1012 may store data necessary (or used) for operations of an application program 1013 and/or a decoding program 1014, and/or may store data generated from the operations of the application program 1013 and the decoding program 1014.

The program storage unit 1011 may include the application program 1013 and/or the decoding program 1014. Here, the program(s) included in the program storage unit 1011 may be a set of instructions and may also be referred to as an instruction set.

The application program 1013 may include pieces of program code for executing various applications operating on the electronic device 1000. That is, the application program 1013 may include pieces of code (or commands) related to various applications executed by a processor 1022.

The decoding program 1014 may include pieces of program code (or commands) for, when performing sidelink-based V2X communication according to embodiments, storing a plurality of LLR values obtained by demodulating second SCI in a plurality of deinterleaving buffers such that the plurality of LLR values are deinterleaved, and decoding the plurality of LLR values stored in the plurality of deinterleaving buffers.

In addition, the electronic device 1000 may include the communication processing unit 1090 configured to perform communication functions for voice communication and data communication. A peripheral device interface 1023 may control connections between the input/output control unit 1040, the communication processing unit 1090, the processor 1022, and/or a memory interface 1021. The processor 1022 perform control such that a plurality of BSs provide corresponding services, by using at least one software program. Here, the processor 1022 may execute at least one program stored in the memory 1010 to provide a service corresponding to the program.

The input/output control unit 1040 may provide an interface between an input/output device such as the display unit 1050 and/or the input device 1060, and the peripheral device interface 1023. The display unit 1050 displays state information, input text, a moving picture, a still picture, and the like. For example, the display unit 1050 may display information about an application program executed by the processor 1022.

The input device 1060 may provide input data generated due to a selection by the electronic device, to the processor unit 1020 through the input/output control unit 1040. Here, the input device 1060 may include a key pad including at least one hardware button, and/or a touch pad configured to detect touch information. For example, the input device 1060 may provide, through the input/output control unit 1040, the processor 1022 with touch information such as a touch, a touch motion, and/or a touch release detected through the touch pad.

Wireless communication devices that perform sidelink-based V2X communication sequentially decode two sets of sidelink control information (SCI) in order to decode a PSSCH. Existing devices and methods for decoding SCI rely on a single triangular interleaver structure to deinterleave LLR values generated by demodulating symbols of the SCI. Due to this reliance on the single triangular structure, only a single LLR value is processed (e.g., deinterleaved) at a time even when multiple LLR values are generated when demodulating each symbol of the SCI. Accordingly, the existing devices and methods incur excessive delay in decoding the SCI because the LLR values are processed one at a time, this reduces PSSCH decoding speed, and thus, reduces communication speed of the existing devices and methods.

However, according to embodiments, improved devices and methods are provided for decoding SCI. For example, the improved devices and methods may use a plurality of divided triangular interleaver structures that enable processing (e.g., deinterleaving) of multiple LLRs, generated by demodulating a symbol of the SCI, at a time (e.g., simultaneously or contemporaneously). By simultaneously or contemporaneously deinterleaving multiple LLRs, the improved devices and methods are able to decode the SCI faster. Accordingly, the improved devices and methods overcome the deficiencies of the existing devices and methods to at least increase SCI and PSSCH decoding speed, thereby increasing communication speed.

According to embodiments, operations described herein as being performed by the wireless communication system 1, any of the first to fourth wireless communication devices 10 to 40, the wireless communication device 100, the transceiver 110, the processor 120, the demodulator 121, the deinterleaver 122, the decoder 125, the descrambler of the wireless communication device 100, the electronic device 1000, the processor unit 1020, the input/output control unit 1040, the communication processing unit 1090, the application program 1013, the decoding program 1014, the peripheral device interface 1023, the processor 1022 and/or a memory interface 1021 may be performed by processing circuitry. The term ‘processing circuitry,’ as used in the present disclosure, may refer to, for example, hardware including logic circuits; a hardware/software combination such as a processor executing software; or a combination thereof. For example, the processing circuitry more specifically may include, but is not limited to, a central processing unit (CPU), an arithmetic logic unit (ALU), a digital signal processor, a microcomputer, a field programmable gate array (FPGA), a System-on-Chip (SoC), a programmable logic unit, a microprocessor, application-specific integrated circuit (ASIC), etc.

The various operations of methods described above may be performed by any suitable device capable of performing the operations, such as the processing circuitry discussed above. For example, as discussed above, the operations of methods described above may be performed by various hardware and/or software implemented in some form of hardware (e.g., processor, ASIC, etc.).

The software may comprise an ordered listing of executable instructions for implementing logical functions, and may be embodied in any “processor-readable medium” for use by or in connection with an instruction execution system, apparatus, or device, such as a single or multiple-core processor or processor-containing system.

The blocks or operations of a method or algorithm and functions described in connection with embodiments disclosed herein may be embodied directly in hardware, in a software module executed by a processor, or in a combination of the two. If implemented in software, the functions may be stored on or transmitted over as one or more instructions or code on a tangible, non-transitory computer-readable medium (the plurality of deinterleaving buffers 123, the temporary buffer 124 and/or the memory 1010). A software module may reside in Random Access Memory (RAM), flash memory, Read Only Memory (ROM), Electrically Programmable ROM (EPROM), Electrically Erasable Programmable ROM (EEPROM), registers, hard disk, a removable disk, a CD ROM, or any other form of storage medium known in the art.

Embodiments have been described herein and illustrated in the drawings. Although embodiments have been described herein by using specific terms, they are used only for the purpose of explaining the inventive concepts and not used to limit the meaning or scope of the claims. Therefore, those of skill in the art will understand that various modifications and other equivalent examples may be derived from embodiments described herein. Therefore, the true technical protection scope of the inventive concepts should be determined by the appended claims.

While the inventive concepts have been particularly shown and described with reference to embodiments thereof, it will be understood that various changes in form and details may be made therein without departing from the spirit and scope of the following claims.

What is claimed is:

1. An operation method of a wireless communication device for performing sidelink-based vehicle-to-everything (V2X) communication, the operation method comprising:
decoding first sidelink control information (SCI) to obtain a first decoding result, the first SCI being contained in a received physical sidelink control channel (PSCCH);
decoding second SCI including
obtaining a plurality of log likelihood ratio (LLR) values by demodulating the second SCI,
storing the plurality of LLR values in a plurality of deinterleaving buffers such that the plurality of LLR values are deinterleaved, and
decoding the plurality of LLR values stored in the plurality of deinterleaving buffers to obtain a second decoding result, the second SCI being contained in a physical sidelink shared channel (PSSCH), and the PSSCH being received based on the first decoding result; and
decoding the PSSCH based on the second decoding result.

2. The operation method of claim 1, wherein the storing of the plurality of LLR values in the plurality of deinterleaving buffers comprises storing the plurality of LLR values in the plurality of deinterleaving buffers such that the plurality of LLR values are deinterleaved based on divided triangular interleaver structures.

3. The operation method of claim 2, wherein the storing of the plurality of LLR values in the plurality of deinterleaving buffers further comprises:
determining a corresponding deinterleaving buffer in which each respective LLR value among the plurality of LLR values is to be stored from among the plurality of deinterleaving buffers based on
the divided triangular interleaver structures, and
an index of each respective LLR value among the plurality of LLR values; and
storing each respective LLR value among the plurality of LLR values in the corresponding deinterleaving buffer among the plurality of deinterleaving buffers based on the determining of the corresponding deinterleaving buffer.

4. The operation method of claim 3, wherein the storing of the plurality of LLR values in the plurality of deinterleaving buffers further comprises:
determining a corresponding address at which each respective LLR value among the plurality of LLR values is to be stored in the plurality of deinterleaving buffers based on a number of LLR values included in a reading-direction line of the divided triangular interleaver structures; and
storing each respective LLR value among the plurality of LLR values at the corresponding address in the corresponding deinterleaving buffer based on the determining of the corresponding address.

5. The operation method of claim 3, wherein
the plurality of LLR values includes two or more LLR values that are obtained by demodulating the same symbol; and
the storing of the plurality of LLR values in the plurality of deinterleaving buffers further comprises storing at least one among the two or more LLR values in a temporary buffer based on determining that the two or more LLR values are to be stored in the same deinterleaving buffer among the plurality of deinterleaving buffers.

6. The operation method of claim 1, wherein the decoding of the plurality of LLR values comprises:
reading the plurality of LLR values from the plurality of deinterleaving buffers based on a reading order; and
decoding the plurality of LLR values according to the reading order.

7. The operation method of claim 6, wherein the reading order is set such that a number of LLR values read at a time from the plurality of deinterleaving buffers decreases, and the plurality of LLR values are read alternately from the plurality of deinterleaving buffers.

8. The operation method of claim 6, wherein the reading of the plurality of LLR values from the plurality of deinterleaving buffers comprises reading a first LLR value among the plurality of LLR values from a temporary buffer based on the first LLR value not being stored in the plurality of deinterleaving buffers.

9. The operation method of claim 1, wherein a number of the plurality of deinterleaving buffers is set based on a method of demodulating the second SCI.

10. A wireless communication device for performing sidelink-based vehicle-to-everything (V2X) communication, the wireless communication device comprising:
a plurality of deinterleaving buffers; and
a processing circuitry configured to
obtain a plurality of log likelihood ratio (LLR) values by demodulating sidelink control information (SCI), the SCI being contained in a physical sidelink shared channel (PSSCH) sequentially received after a physical sidelink control channel (PSCCH), the PSCCH including first SCI, and the SCI contained in the PSSCH being second SCI,
determine a corresponding deinterleaving buffer in which each respective LLR value among the plurality of LLR values is to be stored from among the plurality of deinterleaving buffers such that the plurality of LLR values are deinterleaved,
read the plurality of LLR values from the plurality of deinterleaving buffers based on a reading order, and
decode the plurality of LLR values according to the reading order.

11. The wireless communication device of claim 10, wherein the processing circuitry configured to determine the corresponding deinterleaving buffer in which each respective LLR value among the plurality of LLR values is to be stored from among the plurality of deinterleaving buffers such that the plurality of LLR values are deinterleaved based on divided triangular interleaver structures.

12. The wireless communication device of claim 11, wherein the processing circuitry is configured to:
determine the corresponding deinterleaving buffer in which each respective LLR value among the plurality of LLR values is to be stored from among the plurality of deinterleaving buffers based on
the divided triangular interleaver structures, and
an index of each respective LLR value among the plurality of LLR values; and
store each respective LLR value among the plurality of LLR values in the corresponding deinterleaving buffer among the plurality of deinterleaving buffers based on the determination of the corresponding deinterleaving buffer.

13. The wireless communication device of claim 12, wherein the processing circuitry is configured to:
determine a corresponding address at which each respective LLR value among the plurality of LLR values is to be stored in the plurality of deinterleaving buffers based on a number of LLR values included in a reading-direction line of the divided triangular interleaver structures; and
store each respective LLR value among the plurality of LLR values at the corresponding address in the corresponding deinterleaving buffer based on the determination of the corresponding address.

14. The wireless communication device of claim 10, further comprising:
a temporary buffer,
wherein
the plurality of LLR values includes two or more LLR values that are obtained by demodulating the same symbol, and
the processing circuitry is configured to store at least one among the two or more LLR values in the temporary buffer based on determining that the two or more LLR values are to be stored in the same deinterleaving buffer among the plurality of deinterleaving buffers.

15. The wireless communication device of claim 14, wherein the processing circuitry is configured to read a first LLR value among the plurality of LLR values from the temporary buffer based on the first LLR not being stored in the plurality of deinterleaving buffers.

16. The wireless communication device of claim 10, wherein the reading order is set such that a number of LLR values read at a time from the plurality of deinterleaving buffers decreases, and the plurality of LLR values are read alternately from the plurality of deinterleaving buffers.

17. The wireless communication device of claim 10, wherein a number of the plurality of deinterleaving buffers is set based on a method of demodulating the second SCI.

18. An operation method of a wireless communication device for performing sidelink-based vehicle-to-everything (V2X) communication, the operation method comprising:
decoding first sidelink control information (SCI) to obtain a first decoding result, the first SCI being contained in a received physical sidelink control channel (PSCCH);
decoding second SCI to obtain a second decoding result, the decoding of the second SCI including
obtaining a first log likelihood ratio (LLR) value and a second LLR value by demodulating a first symbol included in the second SCI,
storing the first LLR value in a first deinterleaving buffer, and
storing the second LLR value in a second deinterleaving buffer, the second SCI being contained in a physical sidelink shared channel (PSSCH), and the PSSCH being received based on the first decoding result; and
decoding the PSSCH based on the second decoding result.

19. The operation method of claim 18, wherein the decoding of the second SCI comprises:
obtaining third to (2*n)-th LLR values by demodulating second to n-th symbols included in the second SCI, n being a natural number greater than or equal to 2;
storing each of the third to (2*n)-th LLR values in one of the first deinterleaving buffer, the second deinterleaving buffer or a temporary buffer; and
decoding the first LLR value, the second LLR value and the third to (2*n)-th LLR values to obtain the second decoding result.

20. The operation method of claim 19, further comprising:
reading the first LLR value, the second LLR value and the third to (2*n)-th LLR values from the first deinterleaving buffer, the second deinterleaving buffer and the temporary buffer, based on a reading order,
wherein the decoding of the first LLR value, the second LLR value and the third to (2*n)-th LLR values includes decoding the first LLR value, the second LLR value and the third to (2*n)-th LLR values according to the reading order.
